(19) United States
(12) Patent Application Publication
(10) Pub. No.: US 2005/0056933 A1
(43) Pub. Date: Mar. 17, 2005

(54) Bumped wafer with adhesive layer encompassing bumps and manufacturing method thereof

(75) Inventor: Chih-Ming Chung, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaoshiung (TW)

(21) Appl. No.: 10/942,774

(22) Filed: Sep. 17, 2004

(30) Foreign Application Priority Data
Sep. 17, 2003 (TW) 092125612

(51) Int. Cl. H01L 21/48; H01L 23/52

(52) U.S. Cl. 257/737; 438/613; 257/738; 257/778; 438/108

(57) ABSTRACT

A manufacturing method of a bumped wafer package mainly comprises providing a photosensitive adhesion layer over the active surface of the wafer, forming a plurality of openings in the photosensitive adhesion layer to expose the bonding pads on the active surface of the wafer through an exposure and development processes, forming a plurality of bumps in the openings through printing process and reflowing the bumps with keeping the photosensitive adhesion layer partially cured. In such a manner, the bumps can be well encapsulated in the photosensitive adhesion layer without gaps between the bumps and the photosensitive adhesion layer.

### BACKGROUND OF THE INVENTION

1. Field of Invention

This invention relates to a bumped wafer package. More particularly, the present invention is related to a manufacturing method for such bumped wafer package. According to this manufacturing method, the bumps provided in the bumped wafer package are able to be encompassed by an adhesive layer, made of photosensitive material, which is partially cured before said bumped wafer package is singulated into a plurality of bumped chip packages and such bumped chip packages are mounted to substrates respectively to form a plurality of flip chip packages.

2. Related Art

In this information explosion age, integrated circuits products are used almost everywhere in our daily life. As fabricating technique continue to improve, electronic products having powerful functions, personalized performance and a higher degree of complexity are produced. Nowadays, most electronic products are relatively light and have a compact body. Hence, in semiconductor production, various types of high-density semiconductor packages have been developed. Flip chip is one of the most commonly used techniques for forming an integrated circuits package. Moreover, compared with a wire-bonding package or a tape automated bonding (TAB) package, a flip-chip package uses a shorter electrical path on average and has a better overall electrical performance. In a flip-chip package, the bonding pads on a chip and the contacts on a substrate are connected together through a plurality of bumps formed on the chip by a conventional bumping process and then an underfill material is filled into the gap between the chip and the substrate to encapsulate the bumps so as to well protect the bumps. In such a manner, the reliability of such flip chip package is enhanced.

As mentioned above, in a conventional underfill-filling process, the underfill is dispensed on the substrate and around the bumps of the chip and then flows into the gap as mentioned above to cover the bumps. However, having the bumps fully encapsulated in the underfill and encompassed by the underfill usually spends a lot of working time and it is difficult to keep the reliability of the process of filling the underfill.

In addition, recently, a wafer level packaging process comprising disposing a stress buffer layer on the active surface of the wafer through printing or spin-coating method and then placing a plurality of bumps over the active surface so as to have the bumps encompassed by the stress buffer layer, as disclosed in TW Pub. 523891, and another wafer level packaging process comprising disposing an encapsulation on the active surface of the wafer through a molding method, performing the step of laser-drilling to form openings therein and having a plurality of bumps disposed in the openings, as disclosed in U.S. Pat. No. 6,022,758, are provided. However, according to the mentioned-above technologies and processes, the bumps are formed over the active surface after the stress buffer layer is formed. In such a manner, such bumps are usually not well encapsulated by the stress buffer layer so that the stress buffer layer can not well release external force at the bumps.

Furthermore, another wafer level packaging process disclosed in TW Pub. 411536 comprises the steps of forming a plurality of bumps on the active surface of the wafer and forming an enhancement and protection layer through dispensing an underfill material on the active surface of the wafer to encapsulate the bumps so as to well protect the bumps. However, it is similar with chip package, having the bumps well encapsulated in the underfill material usually spends a lot of working time and it is difficult to keep the reliability of the process of dispensing the underfill material. In addition, when the wafer level package with such enhancement and protection layer formed therein is singulated into a plurality of chip packages and then the chip packages are mounted to substrates respectively to form flip chip packages, the external forces at the bumps in such flip chip packages are not able to be well released for that the enhancement and protection layer is fully cured (C-stage adhesive layer) before such chip packages are mounted on the substrates.

Therefore, providing another bumped wafer package and the manufacturing method thereof to solve the mentioned-above disadvantages is the most important task in this invention.

### SUMMARY OF THE INVENTION

In view of the above-mentioned problems, an objective of this invention is to provide a bumped wafer package and the manufacturing method thereof.

To achieve these and other advantages and in accordance with the purpose of the invention, as embodied and broadly described herein, the invention specifically provides a manufacturing method of forming a bumped wafer package. The manufacturing method mainly comprises providing a photosensitive adhesion layer on the active surface of the wafer, forming a plurality of openings in the photosensitive adhesion layer to expose the bonding pads on the active surface of the wafer through exposure and development processes, forming a plurality of bumps in the openings through printing process and reflowing the bumps with keeping the photosensitive adhesion layer partially cured. In such manner, the bumps can be well encapsulated in the photosensitive adhesion layer without gaps between the bumps and the photosensitive adhesion layer.

As mentioned above, the photosensitive adhesion layer not only serves as a dry film as utilized in conventional bumping process but also an encapsulation or stress buffer layer utilized in conventional wafer level package process. Hence, the manufacturing method of such package can be simplified. Besides, the photosensitive adhesion layer is partially cured after the bumps are formed on the wafer. Thus, after the bumped wafer package is singulated into a plurality of chip packages, the chip packages can be well attached to substrates in flip-chip fashion by reflowing the bumps and performing fully curing process on the photosensitive adhesion layer.

It is to be understood that both the foregoing general description and the following detailed description are exemplary, and are intended to provide further explanation of the invention as claimed.

### BRIEF DESCRIPTION OF THE DRAWINGS

The invention will become more fully understood from the detailed description given herein below illustrations only, and thus are not limitative of the present invention, and wherein:

FIG. 1 is a flow chart illustrating the process flow of a manufacturing method of the bumped wafer package; and

FIGS. 2A to 2E are partially enlarged cross-sectional views showing the progression of steps for forming a bumped wafer package according to the preferred embodiment of this invention; and

FIG. 3 is a cross-sectional view of a bumped chip package attached to a substrate.

### DETAILED DESCRIPTION OF THE INVENTION

The bumped wafer package and the manufacturing method thereof according to the preferred embodiment of this invention will be described herein below with reference to the accompanying drawings, wherein the same reference numbers are used in the drawings and the description to refer to the same or like parts.

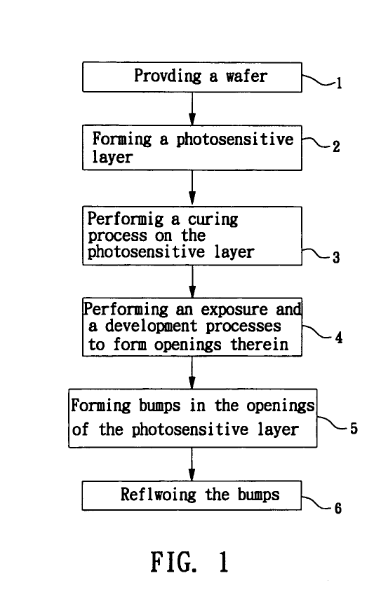

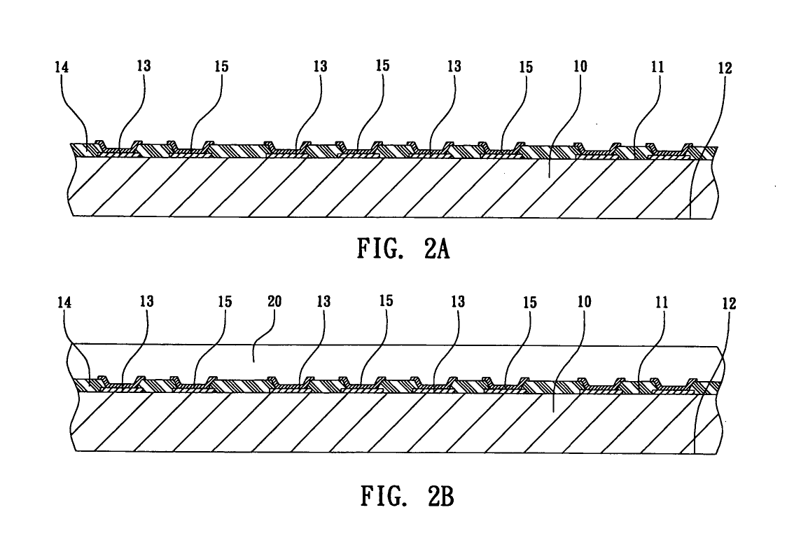

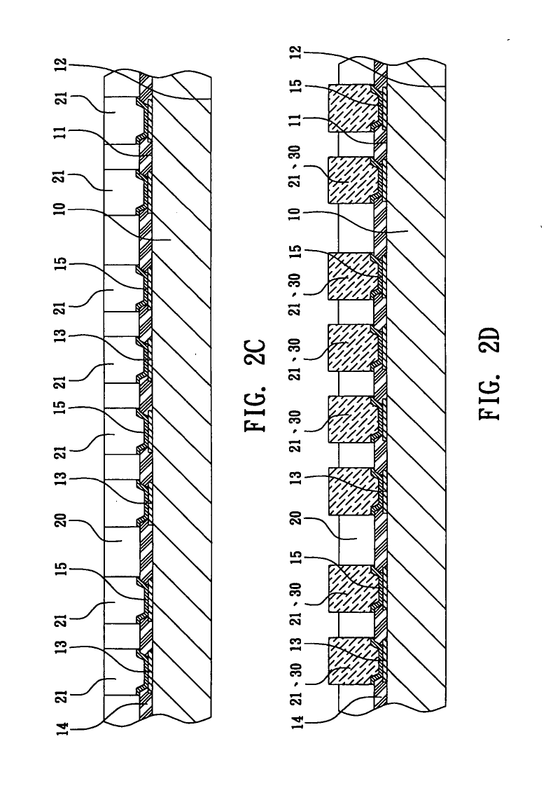

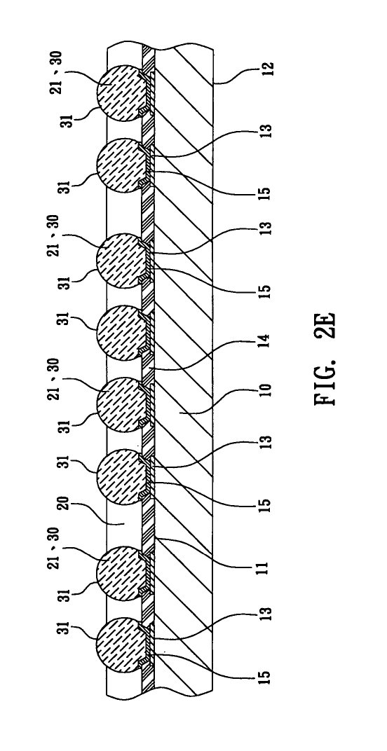

As shown in FIG. 1, it illustrates a process flow of a manufacturing method of the bumped wafer package. The manufacturing method mainly comprises the following steps of providing a wafer as shown in step 1, forming a photosensitive adhesion layer on the wafer as shown in step 2, curing the photosensitive adhesion layer as shown in step 3, performing exposure and development processes to form a plurality of openings in the photosensitive adhesion layer as shown in step 4, forming a plurality of bumps in the openings 5 and reflowing the bumps to shape the bumps into balls as shown in steps 5 and 6. Referring to FIG. 2A, it illustrates the step 1. Therein, the wafer 10 has an active surface 11 and a back surface 12, wherein the active surface 11 has a plurality of bonding pads 13 formed thereon. To be noted, the bonding pads 13 can be portions of redistribution layer, regarded as redistribution pads formed according to redistribution process. Conventionally, there is a passivation layer 14, such as PSG, polyimide (PI) and Benzocyclobutence (BCB), formed on the active surface 11 of the wafer and the bonding pads 13 are exposed out of the passivation layer 14. Specifically, each bonding pad 13 has an under bump metallurgy layer 15, such as Ti—NiV—Cu layer, Al—NiV—Cu layer, Ti—Al—NiV—Cu, Ti—Cu layer and Cr—CrCu—Cu layer, formed thereon for enhancing the attachment of the bumps to the wafer. In this embodiment, the under bump metallurgy layer 15 is formed by the methods of deposition and etching.

Referring to FIG. 2B, it illustrates the step 2 of forming a photosensitive adhesion layer 20 on the active surface 11 of the wafer 10, wherein when the photosensitive adhesion layer 20 is an A-stage adhesive material, the photosensitive adhesion layer 20 can be disposed on the active surface 11 through printing, and when the photosensitive adhesion layer 20 is a film, the photosensitive adhesion layer 20 can be disposed on the active surface 11 through the method of laminating. Preferably, when the photosensitive adhesion layer 20 is an A-stage adhesive layer, after the step 2, a curing process, the step 3, is performed to have the photosensitive adhesion layer 20 partially cured to be transferred into a B-stage adhesive layer. In this embodiment, the curing process is performed, by heating the photosensitive adhesion layer 20 to a temperature of about 120° C. Generally, the curing process is performed at a temperature being lower than the temperature at which the photosensitive adhesion layer becomes completely thermosetting. Namely, the photosensitive adhesion layer 20 under partially cured condition as mentioned above is regarded as being not completely thermosetting. However, such temperature limitation usually depends upon the type of photosensitive adhesion layer.

Next, referring to FIG. 2C, it illustrates the step 4. The photosensitive adhesion layer 20 is kept partially cured when a exposure and a development processes are performed to form a plurality of openings 21 in the photosensitive adhesion layer 20, wherein the openings 21 expose the bonding pads 13 of the wafer 10.

Then, referring to FIG. 2D, it illustrates the step 5. A plurality of bumps 30 are formed in the openings 21 and attached to the wafer 10 by printing solder materials in the openings. To be noted, the step 5 shall be performed at a temperature lower than the temperature at which the photosensitive adhesion layer 20 is fully cured. To be noted, the photosensitive adhesion layer 20 under fully cured is regarded as being completely thermosetting.

Next, referring to FIG. 2E, it illustrates the step 6. In this embodiment, the bumps 30 are eutectic bumps, 63/37 solder bumps, or solder bumps with other composition, and the solder bumps 30 are reflowed at a temperature ranged from 180° C. to 220° C. for 3 seconds to 5 seconds in this step 6. Because the photosensitive adhesion layer 20 is kept partially cured at the step 6 of reflowing bumps, the bumps 30 can be well encapsulated by the photosensitive adhesion layer 20 due to its good flowability. Finally, the bumps 30 are protruded from the photosensitive adhesion layer 20 for serving as electrical terminals to electrically connect to external devices, such as substrates. At this time, the bumped wafer package is completely formed.

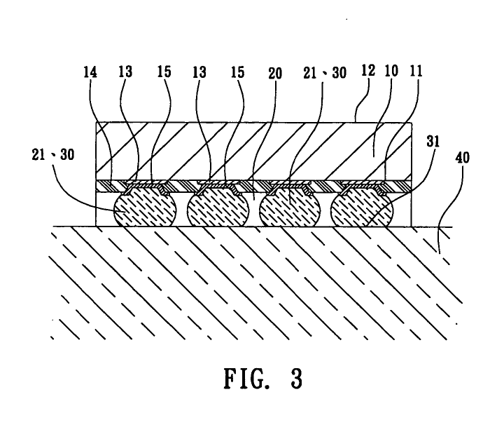

Moreover, referring to FIG. 3, when the bumped wafer package is singulated into a plurality of chip packages, such chip packages can be directly mounted to the corresponding substrates in a flip-chip fashion respectively and then performing a heating process to have the photosensitive adhesion 20 layer fully cured and have the bumps transferred into reflowed bumps to form flip chip packages without utilizing underfill dispensing process and dry film laminating step in bumping process. Thus, the manufacturing method of such flip chip package is simplified. At this time, the photosensitive adhesion layer is a C-stage adhesive layer. Namely, as mentioned above, the C-stage adhesive layer is completely thermosetting.

Although the invention has been described in considerable detail with reference to certain preferred embodiments, it will be appreciated and understood that various changes and modifications may be made without departing from the spirit and scope of the invention as defined in the appended claims.

1. A manufacturing method of forming a bumped wafer package with a photosensitive adhesion layer formed thereon and encompassing bumps therein, the method comprising the steps of:
providing a wafer with an active surface and a plurality of bonding pads formed on the active surface;
disposing the photosensitive adhesion layer over the active surface;
forming a plurality of openings in the photosensitive adhesion layer so as to have the bonding pads exposed out of the openings respectively; and
forming a plurality of bumps in the openings of the photosensitive adhesion layer.

2. The method of claim 1, further comprising performing a curing process to have the photosensitive adhesion layer partially cured before forming the bumps in the openings.

3. The method of claim 2, wherein when the photosensitive adhesion layer is an A-stage adhesive layer before performing the curing process, the photosensitive adhesion layer is transferred into a B-stage adhesive layer after performing the curing process.

4. The method of claim 3, wherein the curing process is performed at a temperature being lower than the temperature at which the photosensitive adhesion layer becomes completely thermosetting.

5. The method of claim 1, wherein the photosensitive adhesion layer is a B-stage adhesive layer.

6. The method of claim 1, further comprising performing a reflow process to have the bumps shaped into balls after forming the bumps in the openings of the photosensitive adhesion layer.

7. The method of claim 6, wherein the bumps are protruded from the photosensitive adhesion layer.

8. The method of claim 1, wherein the bumps are formed in the openings through the step of printing solder material into the openings of the photosensitive adhesion layer.

9. The method of claim 3, wherein the photosensitive adhesion layer is disposed on the active surface of the wafer through performing a screen-printing process.

10. The method of claim 1, wherein the photosensitive adhesion layer is disposed on the active surface through placing a photosensitive adhesion film on the active surface of the wafer.

11. The method of claim 1, further forming an under bump metallurgy layer on the bonding pad.

12. The method of claim 1, wherein the step of forming the openings in the photosensitive adhesion layer comprises performing an exposure process and a development process.

13. A manufacturing method of forming a bumped chip package with a photosensitive adhesion layer encompassing bumps therein, the method comprising the steps of:
providing a wafer with an active surface and a plurality of bonding pads formed on the active surface;
disposing the photosensitive adhesion layer on the active surface of the wafer;
forming a plurality of openings in the photosensitive adhesion layer so as to have the bonding pads exposed out of the openings respectively;
forming a plurality of bumps in the openings of the photosensitive adhesion layer to form a bumped wafer;
singulating the bumped wafer into a plurality of bumped chips wherein each bumped chip has a unit active surface and a unit photosensitive adhesion layer formed on the unit active surface;
attaching and electrically connecting the bumped chip to a substrate;
performing a heating process to have the bumps reflowed and the unit photosensitive adhesion layer fully cured so as to have the bumps transferred into reflowed bumps and have unit photosensitive adhesion layer transferred into a C-stage adhesive layer.

14. The method of claim 13, wherein the step of forming the openings in the photosensitive adhesion layer comprises performing an exposure process and a development process.

15. A bumped chip package, comprising:
a chip having a an active surface and a plurality of bonding pads formed on the active surface;
a photosensitive adhesion layer formed on the active surface, wherein the photosensitive adhesion layer has a plurality of openings exposing the bonding pads respectively and is fully cured;
a plurality of bumps formed in the openings of the photosensitive adhesion layer; and
a substrate attached to the bumps.

16. The bumped chip package of claim 15, wherein the bumps are protruded from the photosensitive adhesion layer.

17. The bumped chip package of claim 15, wherein an under bump metallurgy layer is formed on each said bonding pads.

18. The bumped chip package of claim 17, wherein the bumps are attached onto the under bump metallurgy layer.

19. The bumped chip package of claim 15, wherein the photosensitive adhesion layer is a C-stage adhesive layer.

20. A bumped wafer package, comprising:
a wafer having a an active surface and a plurality of bonding pads formed on the active surface;
a photosensitive adhesion layer formed on the active surface, wherein the photosensitive adhesion layer has a plurality of openings exposing the bonding pads respectively and is partially cured; and
a plurality of bumps formed in the openings of the photosensitive adhesion layer.

21. The bumped wafer package of claim 20, wherein the bumps are protruded from the photosensitive adhesion layer.

22. The bumped wafer package of claim 21, wherein an under bump metallurgy layer is formed on each said bonding pad.

23. The bumped wafer package of claim 22, wherein the bumps are attached onto the under bump metallurgy layer.

24. The bumped wafer package of claim 21, wherein the photosensitive adhesion layer is a B-stage adhesive layer.
